(19) United States
(12) Patent Application Publication
(10) Pub. No.: US 2003/0164552 A1
(43) Pub. Date: Sep. 4, 2003

(54) Under-ball metallic layer

(76) Inventors: Ho-Ming Tong, Taipei (TW); Chun-Chi Lee, Kaohsiung (TW); Jen-Kuang Fang, Pingtung Hsien (TW); Min-Lung Huang, Kaohsiung (TW); Jau-Shoung Chen, Hsinchu Hsien (TW); Ching-Huei Su, Kaohsiung (TW); Chao-Fu Weng, Tainan (TW); Yung-Chi Lee, Kaohsiung (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/063,575

(22) Filed: May 3, 2002

(30) Foreign Application Priority Data
Mar. 1, 2002 (TW) 91103733

(51) Int. Cl. H01L 23/48; H01L 23/52; H01L 29/40

(52) U.S. Cl. 257/779

(57) ABSTRACT

An under-ball metallic layer on a contact pad with the junction between the under-ball metallic layer and the contact pad made from copper material. The under-ball metallic layer comprises an adhesion layer, a barrier layer and a wettable layer. The adhesion layer is formed over the contact pad and made from a material such as titanium-tungsten alloy or chromium. The barrier layer is formed over the adhesion layer and made from a material such as nickel-vanadium alloy. The wettable layer is formed over the barrier layer and made from a material such as copper, palladium or gold.

### CROSS REFERENCE TO RELATED APPLICATIONS

This application claims the priority benefit of Taiwan application serial no. 91103733, filed Mar. 1, 2002.

### BACKGROUND OF INVENTION

1. Field of Invention

The present invention relates to an under-ball metallic layer structure. More particularly, the present invention relates to an under-ball metallic layer capable of forming over a bonding pad made of copper.

2. Description of Related Art

In this information explosion age, electronic products are used everywhere including the food processing industry, educational institutes, recreational centers, offices and homes. As electronic fabrication techniques continue to improve, more functionally powerful and personalized products are pouring out into the marketplace. In addition, the electronic products are becoming more aesthetically appealing, light weight and compact. In semiconductor manufacturing, width of metallic interconnects inside an integrated circuit has changed from 0.25 μm to 0.18 μm. The current trend is towards a line width of 0.15 μm to 0.13 μm. However, as width of metallic interconnects shrinks, many other problems also arise. To name a few, overall resistance and current density of the metallic interconnects will go up considerably leading to an intensification of electromigration. Electromigration occurs when a thin film of conductive layer is subject to an intense internal electric field. Some of the metallic atoms migrate along the crystal boundaries of the film in the direction of the current motion. Ultimately, the number of atoms in the conductive region decreases leading to a smaller metallic line cross-section. Finally, the metallic line may break forming an open circuit. In the past, the most commonly used material for forming the metallic interconnects was aluminum. Since aluminum is easy to form (sputtering, evaporation plating, chemical vapor deposition, dry etching, wet etching can all be applied to aluminum) and has a high affinity for silicon dioxide, aluminum is the principle material forming metallic interconnects. Nevertheless, aluminum material has little resistance against electromigration. Hence, as dimension of metallic interconnects continue to shrink, aluminum material must be replaced. Furthermore, aluminum has a relative high resistivity and may lead to greater resistance-capacitance delay.

To improve the electrical properties of the metallic interconnects, a low electrical resistance, high electromigration resistant metallic material such as copper is used. Earlier semiconductor fabricators refrained from using copper because copper has a high diffusion coefficient. Hence, when a copper layer is in contact with a silicon or silicon dioxide layer, the copper atoms rapidly diffuse into the substrate leading to deep layer energy gap problem. Furthermore, copper is easily oxidized and may react with other material at a low temperature. Moreover, an effective means of dry etching the copper is absent. However, following the improvement in material processing and fabrication techniques, the introduction of various types of barrier layers and the successful implementation of damascene processes and copper chemical-mechanical polishing operations, the aforementioned problems for using copper are being eliminated one by one. At present, most silicon chip have copper bonding pads.

To match the copper bonding pads in flip-chip manufacturing, titanium material is used to form the adhesion layer inside an under-ball metallic layer. In general, a hydrofluoric (HF) acid containing etchant is used to etch the titanium layer. However, hydrofluoric acid is highly toxic to humans. Moreover, if polyimide (PI) is used as a passivation material to protect the silicon wafer, the attachment of bumps to corresponding bonding pads is highly unreliable because bondability between titanium and polyimide is poor.

### SUMMARY OF INVENTION

Accordingly, one object of the present invention is to provide an under-ball metallic layer structure capable of forming over a copper bonding pad and so that the etchant for etching the adhesion layer inside the under-ball metallic layer is intrinsically less toxic.

A second object of this invention is to provide an under-ball metallic layer structure having an adhesion layer made from either chromium or titanium-tungsten alloy because chromium or titanium-tungsten alloy has higher bondability with polyimide. Hence, if polyimide is used as a passivation layer to protect the silicon wafer, bumps are more firmly attached to the bonding pads.

Note in the following description that the use of the preposition “over” as in “a second layer is formed over a first layer” means that the second layer is either in contact with the first layer or simply above the first layer.

To achieve these and other advantages and in accordance with the purpose of the invention, as embodied and broadly described herein, the invention provides an under-ball metallic layer over a contact pad such as a copper pad. The under-ball metallic layer structure includes an adhesion layer, a barrier layer and a wettable layer. The adhesion layer is formed over the contact pad and made from titanium-tungsten alloy or chromium. The barrier layer is formed over the adhesion layer and made from nickel-vanadium alloy. The wettable layer is formed over the barrier layer and made from copper, palladium or gold.

In brief, the under-ball metallic layer according to this invention and the copper layer may be fabricated close together so that the bump is formed over the copper bonding pad. Since the adhesion layer within the under-ball metallic layer is a titanium-tungsten alloy or chromium, a non-toxic etchant containing hydrogen peroxide (H₂O₂), ethylenediaminetetraacetic (EDTA) and potassium sulfate (K₂SO₄) may be used to etch titanium-tungsten alloy while a non-toxic etchant containing hydrochloric (HCl) acid may be used to etch chromium. Hence, the adhesion layer inside the under-ball metallic layer can be etched without producing any harmful chemicals.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1 through 8 are schematic magnified cross-sectional views showing the steps for forming producing a bump over a silicon wafer according to a first preferred embodiment of this invention.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

FIGS. 1 through 8 are schematic magnified cross-sectional views showing the steps for forming producing a bump over a silicon wafer according to a first preferred embodiment of this invention. As shown in FIG. 1, a silicon wafer 110 is provided. The silicon wafer 110 has an active surface 112 with a passivation layer 114 and a plurality of bonding pads (only one is shown) thereon. The passivation layer 114 exposes the bonding pads 116. The bonding pads 116 are made from a material such as copper or a copper-aluminum alloy.

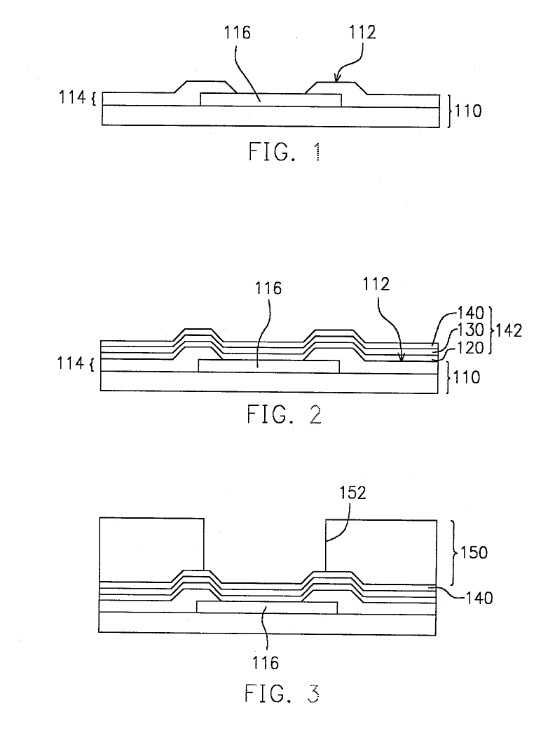

As shown in FIG. 2, an adhesion layer 120 is formed over the active surface 1112 of the wafer 110 by sputtering. The adhesion layer 120 covers the bonding pads 116 and the passivation layer 114. The adhesion layer 120 having a thickness between 800 Å to 2000 Å is made from a material such as titanium-tungsten alloy or chromium. A barrier layer 120 is formed over the adhesion layer 120 by sputtering or electroplating. The barrier layer 130 having a thickness between 1500 Å to 3500 Å is made from a material such as nickel-vanadium alloy. A wettable layer 140 is formed over the barrier layer 130 by sputtering or electroplating. The wettable layer 140 having a thickness between 2000 Å to 9000 Å is made from a material such as copper, palladium or gold. This completes the fabrication of an under-ball metallic layer 142. In fact, the under-ball metallic layer 142 is a composite layer comprising the adhesion layer 120, the barrier layer 140 and the wettable layer.

As shown in FIG. 3, a photolithographic operation is conducted to from a photoresist layer 150 over the wettable layer 140. Through photo-exposure and chemical development, a pattern (not shown) is transferred to the photoresist layer 150 so that a plurality of openings 152 (only one is shown) is formed in the photoresist layer 150. Each opening 152 exposes the wettable layer 140 above the bonding pad 116.

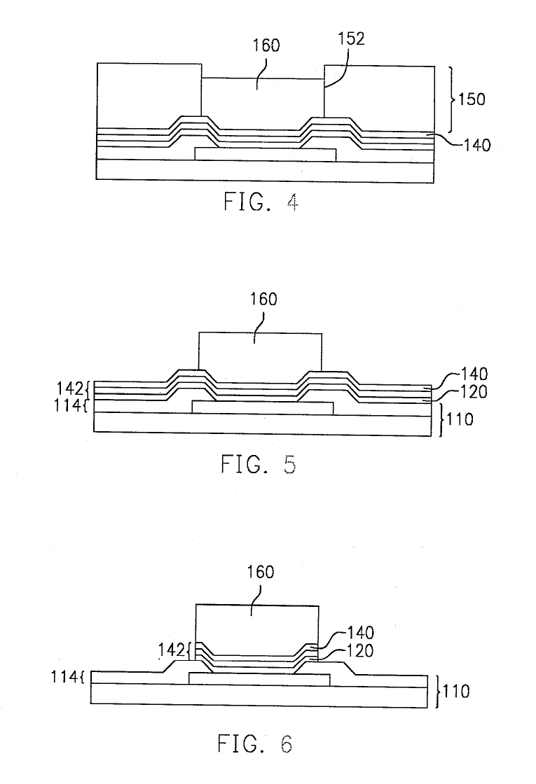

As shown in FIG. 4, an electroplating operation is conducted by depositing metallic material into the openings 152 of the photoresist layer 150 to form a plurality of solder blocks 160 (only one is shown). The solder blocks 160 made from a material such as lead-tin alloy covers the wettable layer 140.

As shown in FIGS. 4 and 5, the photoresist layer 150 is removed from the wettable layer 140.

As shown in FIGS. 5 and 6, the exposed under-ball metallic layer 142 is removed by etching so that only the residual under-ball metallic layer 142 underneath the solder blocks 160 remains. Hence, the passivation layer 114 on the wafer 110 is exposed. To etch the adhesion layer 120, a non-toxic etchant containing hydrogen peroxide (H₂O₂), ethylenediaminetetraacetic (EDTA) and potassium sulfate (K₂SO₄) is used if the adhesion layer 120 is a titanium-tungsten alloy layer. On the other hand, a non-toxic etchant containing hydrochloric (HCl) acid is used if the adhesion layer 120 is a chromium layer.

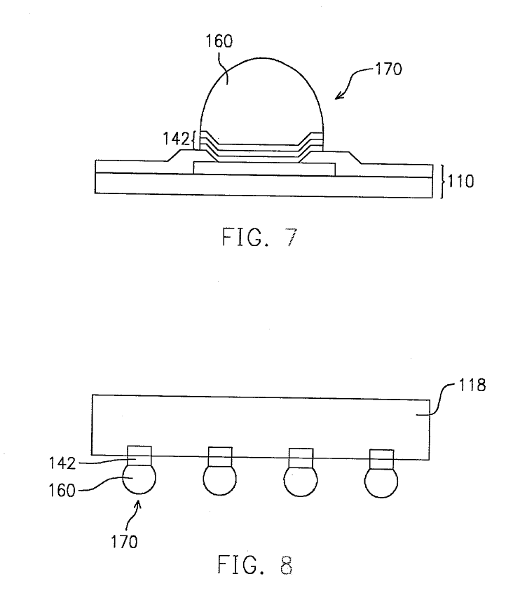

As shown in FIG. 7, a reflux operation is carried out by sprinkling flux material over the wafer 110 and heating the wafer 110 so that the solder blocks 160 soften into a blob of material having a hemispherical profile. This completes the fabrication of bumps 170. Each bump actually comprises the under-ball metallic layer 162 and the solder block 160. Finally, the wafer 110 is sliced into a plurality of chips 118 as shown in FIG. 8.

In the aforementioned under-ball metallic layer 142, the adhesion layer 120 is made from a material such as titanium, titanium-tungsten alloy or chromium. Titanium, titanium-tungsten alloy and chromium all have good bondability with copper. Hence, the under-ball metallic layer 142 according to this invention is suitable for fabricating over the copper bonding pads 16. Similarly, due to the bondability between chromium or titanium-tungsten alloy with polyimide, stability of the bumps 170 over the bonding pads 116 is improved if the passivation layer 114 over the wafer 110 is made from polyimide.

The fabrication of bumps is not limited to electroplating. Other processes such as wire printing method may be used. Since these processes are familiar to bump fabrication technicians, detailed description is not repeated here.

The barrier layer or wettable layer with special material constituents is not limited to the aforementioned applications. Other types of material layer may also be fabricated using the techniques as well.

In addition, the solder blocks can be made from a material such as gold, lead-tin alloy or lead-free metal.

The under-ball metallic layer according to this invention need not be limited to just three layers (the adhesion layer, the barrier layer and the wettable layer). Other numbers of conductive layers is possible. For example, the under-ball metallic layer can be a structure with four layers, including a chromium layer, a chromium-copper alloy layer, a copper layer and a silver layer. Alternatively, the under-ball metallic layer can be a structure with two layers, including a lower layer such as a titanium-tungsten alloy layer or a titanium layer and an upper layer such as a copper layer, a nickel layer or a gold layer.

Although the under-ball metallic layers are directly formed over bonding pads on the active surface of a silicon wafer in the aforementioned embodiment, the bumps may also form over copper contact pads elsewhere. For example, the under-ball metallic layer may form over a redistribution layer after the redistribution layer is formed on a silicon wafer. Since the fabrication of a redistribution layer is familiar to those skilled in the art, detailed description is omitted. In general, the contact pads are made from a material such as copper or copper-aluminum alloy.

In summary, the embodiment of this invention discloses the following types of under-ball metallic layers:

| | Adhesion Layer | Barrier Layer | Wettable Layer |
|---|---|---|---|
| First Type | Titanium-tungsten | Nickel-vanadium | Copper |
| | Alloy | Alloy | |
| Second Type | Titanium-tungsten | Nickel-vanadium | Palladium |
| | Alloy | Alloy | |
| Third Type | Titanium-tungsten | Nickel-vanadium | Gold |
| | Alloy | Alloy | |
| Fourth Type | Chromium | Nickel-vanadium | Copper |
| | | Alloy | |
| Fifth Type | Chromium | Nickel-vanadium | Palladium |
| | | Alloy | |
| Sixth Type | chromium | Nickel-vanadium | Gold |
| | | Alloy | |

All the six types of under-ball metallic layer are suitable for fabricating over copper bonding pads. A non-toxic etchant containing hydrogen peroxide (H₂O₂), ethylenediaminetetraacetic (EDTA) and potassium sulfate (K₂SO₄) is used to etch the adhesion layer if the adhesion layer is a titanium-tungsten alloy layer. On the other hand, a non-toxic etchant containing hydrochloric (HCl) acid is used to etch the adhesion layer if the adhesion layer is a chromium layer. Hence, the adhesion layer within the under-ball metallic layer is etched using an etchant with low toxicity. Another advantage of using chromium or titanium-tungsten alloy to fabricate the adhesion layer is that chromium or titanium-tungsten alloy has good bondability with polyimide. Thus, if the passivation layer over the wafer is made of polyimide, the adhesion of bumps with the bonding pads greatly improves.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. An under-ball metallic layer structure over a contact pad such that the contact interface between the under-ball metallic layer and the contact pad is made from a material containing copper, the structure comprising:
an adhesion layer over the contact pad, wherein the adhesion layer is made from titanium-tungsten;
a barrier layer over the adhesion layer; and
a wettable layer over the barrier layer.

2. The structure of claim 1, wherein material constituting the barrier layer is a nickel-vanadium layer.

3. The structure of claim 1, wherein material constituting the wettable layer is selected from a group consisting of copper, palladium and gold.

4. The structure of claim 1, wherein the adhesion layer has a thickness between about 800 Å to 2000 Å.

5. The structure of claim 1, wherein the barrier layer has a thickness between about 1500 Å to 3500 Å.

6. The structure of claim 1, wherein the wettable layer has a thickness between about 2000 Å to 9000 Å.

7. An under-ball metallic layer structure over a contact pad such that the contact interface between the under-ball metallic layer and the contact pad is made from a material containing copper, the structure comprising:
an adhesion layer over the contact pad, wherein the adhesion layer is made from chromium;
a barrier layer over the adhesion layer; and
a wettable layer over the barrier layer.

8. The structure of claim 7, wherein material constituting the barrier layer is a nickel-vanadium layer.

9. The structure of claim 7, wherein material constituting the wettable layer is selected from a group consisting of copper, palladium and gold.

10. The structure of claim 7, wherein the adhesion layer has a thickness between about 800 Å to 2000 Å.

11. The structure of claim 7, wherein the barrier layer has a thickness between about 1500 Å to 3500 Å.

12. The structure of claim 7, wherein the wettable layer has a thickness between about 2000 Å to 9000 Å.

13. A chip structure having bumps thereon, comprising:
a silicon chip having an active surface with a passivation layer and a plurality of bonding pads thereon, wherein the passivation layer exposes the bonding pads and material forming the bonding pads contains copper;
an adhesion layer over the bonding pads, wherein material forming the adhesion layer is titanium-tungsten alloy;
a barrier layer over the adhesion layer, wherein material forming the barrier layer is nickel-vanadium alloy;
a wettable layer over the barrier layer, wherein material forming the wettable layer includes copper; and
a plurality of solder blocks over the wettable layer.

14. The chip structure of claim 13, wherein the adhesion layer has a thickness between about 800 Å to 2000 Å.

15. The chip structure of claim 13, wherein the barrier layer has a thickness between about 1500 Å to 3500 Å.

16. The chip structure of claim 13, wherein the wettable layer has a thickness between about 2000 Å to 9000 Å.

17. A chip structure having bumps thereon, comprising:
a silicon chip having an active surface with a passivation layer and a plurality of bonding pads thereon, wherein the passivation layer exposes the bonding pads and material forming the bonding pads contains copper;
an adhesion layer over the bonding pads, wherein material forming the adhesion layer is chromium;
a barrier layer over the adhesion layer, wherein material forming the barrier layer is nickel-vanadium alloy;
a wettable layer over the barrier layer, wherein material forming the wettable layer includes copper; and
a plurality of solder blocks over the wettable layer.

18. The chip structure of claim 17, wherein the adhesion layer has a thickness between about 800 Å to 2000 Å.

19. The chip structure of claim 17, wherein the barrier layer has a thickness between about 1500 Å to 3500 Å.

20. The chip structure of claim 17, wherein the wettable layer has a thickness between about 2000 Å to 9000 Å.

21. A chip structure having bumps thereon, comprising:
a silicon chip having an active surface with a passivation layer and a plurality of bonding pads thereon, wherein the passivation layer exposes the bonding pads and material forming the bonding pads contains copper;
an adhesion layer over the bonding pads, wherein material forming the adhesion layer is titanium-tungsten alloy;
a barrier layer over the adhesion layer;
a wettable layer over the barrier layer; and
a plurality of solder blocks over the wettable layer.

22. The chip structure of claim 21, wherein material constituting the barrier layer is nickel-vanadium alloy.

23. The chip structure of claim 21, wherein material constituting the wettable layer is selected from a group consisting of copper, palladium and gold, and that the solder block material and the wettable layer material may diffuse into each other.

24. The chip structure of claim 21, wherein material forming the passivation layer includes polyimide.

25. The chip structure of claim 21, wherein the adhesion layer has a thickness between about 800 Å to 2000 Å.

26. The chip structure of claim 21, wherein the barrier layer has a thickness between about 1500 Å to 3500 Å.

27. The chip structure of claim 21, wherein the wettable layer has a thickness between about 2000 Å to 9000 Å.

28. A chip structure having bumps thereon, comprising:
a silicon chip having an active surface with a passivation layer and a plurality of bonding pads thereon, wherein the passivation layer exposes the bonding pads and material forming the bonding pads contains copper;
an adhesion layer over the bonding pads, wherein material forming the adhesion layer is chromium;
a barrier layer over the adhesion layer;
a wettable layer over the barrier layer; and
a plurality of solder blocks over the wettable layer.

29. The chip structure of claim 28, wherein material constituting the barrier layer is nickel-vanadium alloy.

30. The chip structure of claim 28, wherein material constituting the wettable layer is selected from a group consisting of copper, palladium and gold, and that the solder block material and the wettable layer material may diffuse into each other.

31. The chip structure of claim 28, wherein material forming the passivation layer includes polyimide.

32. The chip structure of claim 28, wherein the adhesion layer has a thickness between about 800 Å to 2000 Å.

33. The chip structure of claim 28, wherein the barrier layer has a thickness between about 1500 Å to 3500 Å.

34. The chip structure of claim 28, wherein the wettable layer has a thickness between about 2000 Å to 9000 Å.

35. An under-ball metallic layer on a contact pad made from copper, wherein the contact interface between the under-ball metallic layer and the contact pad is made from titanium-tungsten alloy.

36. An under-ball metallic layer on a contact pad made from copper, wherein the contact interface between the under-ball metallic layer and the contact pad is made from chromium.
